(19) United States
(12) Patent Application Publication
(10) Pub. No.: US 2016/0155657 A1
(43) Pub. Date: Jun. 2, 2016

(54) SURFACE PROFILE MODIFICATIONS FOR EXTENDED LIFE OF CONSUMABLE PARTS IN SEMICONDUCTOR PROCESSING EQUIPMENT

(71) Applicant: Applied Materials, Inc., Santa Clara, CA (US)

(72) Inventors: Ramesh GOPALAN, Fremont, CA (US); Simon YAVELBERG, Cupertino, CA (US)

(21) Appl. No.: 14/955,771

(22) Filed: Dec. 1, 2015

Related U.S. Application Data
(60) Provisional application No. 62/086,520, filed on Dec. 2, 2014.

(51) Int. Cl. H01L 21/687; H01L 21/67

(52) U.S. Cl. CPC H01L 21/68721; H01L 21/67069

(57) ABSTRACT

Examples of the disclosure generally relate to a component for use in a semiconductor process chamber includes a body having machined surfaces including a processing facing surface configured to face a processing region of the semiconductor process chamber, and a profile disposed on the plasma facing surface wherein the profile increases the surface area of the processing facing surface without increasing a base surface area.

### CROSS-REFERENCE TO RELATED APPLICATIONS

This application claims benefit of U.S. Provisional Application Ser. No. 62/086,520, filed Dec. 2, 2014 (Attorney Docket No. APPM/21747USL), of which is incorporated by reference in its entirety.

### BACKGROUND

1. Field of the Disclosure

Embodiments of the present disclosure generally relate to a component for a semiconductor process chamber. More specifically, the disclosure relates to a component for a semiconductor process chamber having a surface profile for extending the service life.

2. Description of the Related Art

Humanity and the global economy has benefited greatly from manufacturing of ever more complicated electronic chips at ever decreasing costs, a trend first described by Moore's law nearly 5 decades ago. The Information age is now accessible to nearly everyone on the planet through smartphones and computer servers that enable web search and social media networks. Processing these complicated electronic chips on substrates while reducing costs requires getting the processing conditions stable and repeatable for the billions of transistors on hundreds of chips, on thousands of substrates processed through each substrate fabrication, every week of every year. The processing process chamber used to manufacture such substrates need to be able to run for longer periods of time without interruption for repair or preventive maintenance in order to maximize the output of good substrates.

The semiconductor process chamber includes various components, some of which define a processing region within the chamber with respect to the substrate. For example, a semiconductor process chamber can include components, such as rings, shields, liners, and the like. Many semiconductor substrates are processed in the presence of a processing gas or gases that form a plasma within the processing region. Over time, the plasma consumes components in the chamber having surfaces exposed to the plasma necessitating the maintenance of the chamber.

Therefore, there is a need for an improved chamber requiring less maintenance.

### SUMMARY

In one example implementation, a component for use in a semiconductor process chamber includes a body having machined surfaces including a processing facing surface configured to face a processing region of the semiconductor process chamber, and a profile disposed on the processing facing surface wherein the profile increases the surface area of the processing facing surface without increasing a base surface area.

### BRIEF DESCRIPTION OF THE DRAWINGS

So that the manner in which the above recited features of the present disclosure can be understood in detail, a more particular description of the invention, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic, cross-sectional view of a semiconductor substrate process system according to one embodiment of the disclosure.

FIG. 2 is a cross-sectional side view of a ring assembly according to an embodiment.

FIG. 3 is a large scale illustration for a portion of an upper surface of the ring assembly of FIG. 2.

FIG. 4 illustrates a partial list of patterns suitable for use on the upper surface of the ring assembly.

To facilitate understanding, identical reference numerals have been used, where possible, to designate identical elements that are common to the figures. It is also contemplated that elements and features of one embodiment may be beneficially incorporated on other embodiments without further recitation.

### DETAILED DESCRIPTION

Embodiments of the disclosure generally provide a chamber component for uses in a semiconductor process chamber. The chamber components have a surface profile which extends the service life of the chamber component in the presence of processing gas. In an example implementation, a chamber component includes a body having a plurality of surfaces, the plurality of surfaces including a first surface configured to interface with a support member of the semiconductor process chamber, and a second surface configured to face a processing region of the chamber. The second surface is exposed to plasma formed in the processing region and hence may be referred to herein as a “plasma facing surface.” During substrate processing, the plasma in the processing chamber reacts with and/or erodes the plasma facing surface of the chamber component during plasma processing of the substrate. The plasma facing surfaces of the component can be modified to have a surface profile, for example a wave-form surface profile, such as a sinusoidal surface profile, which effectively increases the surface area of the plasma facing surfaces to maximize the service life of the chamber component. It should be appreciated that the second surface may be a processing facing surface eroded by gases or other materials other than plasma. Various techniques are described herein for improving the service life of chamber components by modifying the surface profile of the plasma facing surface to reduce erosion of the chamber component from processing gases.

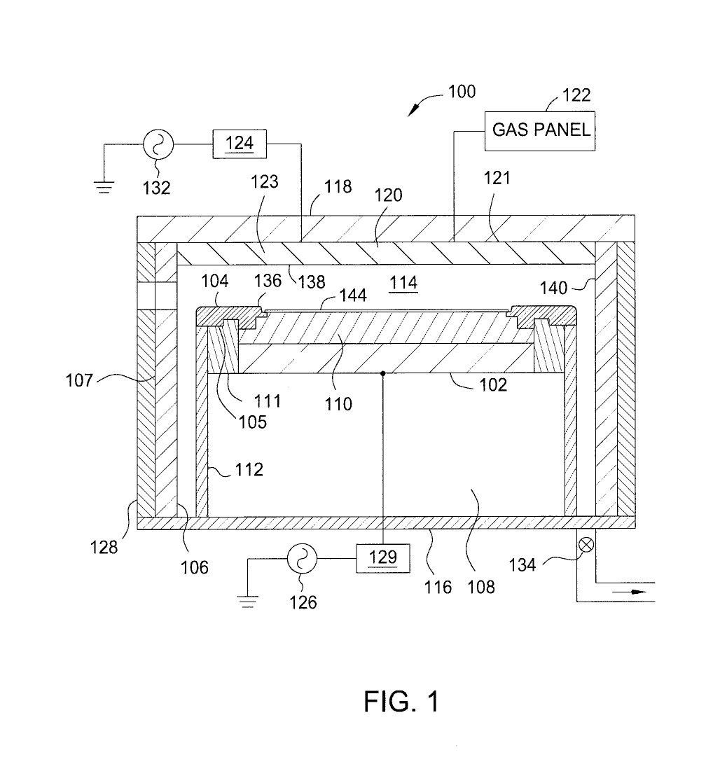

FIG. 1 is a schematic, cross sectional view of a semiconductor substrate process system according to one embodiment of the disclosure. The illustrated process system generally comprises a plasma process chamber 100 suitable for etching, chemical vapor deposition (CVD), or other plasma process. The process chamber 100 includes a cylindrical side wall 128, a bottom wall 116, and a top wall or lid 118. The process chamber 100 may be utilized alone or as a processing module of an integrated semiconductor substrate processing system or cluster tool. A substrate support 108 is disposed in the process chamber 100 configured to support a semiconductor substrate 144 or other workpiece. The substrate support 108 is disposed below an anode electrode 120 mounted proximate the lid 118. The anode electrode 120 may be perforated to function as a gas inlet through which process gases enter the process chamber 100 (e.g., the anode electrode 120 may be a showerhead 123) from a gas source 122. The anode electrode 120 can be coupled to an RF power source 132 through a matching network 124.

The interior of the process chamber 100 is a high vacuum vessel that is coupled through a throttle valve (not shown) to a vacuum pump 134. During processing, the semiconductor substrate 144 is placed on the substrate support 108 and the interior of the process chamber 100 is pumped down to a near vacuum environment. One or more processing gases is/are supplied, for example through the anode electrode 120 (e.g., showerhead), into a processing region 114. The processing gas or gases is/are ignited into a plasma by applying power from the RF power source 132 to the anode electrode 120 and/or the RF power source 132 to the substrate support 108 while applying power from a bias source (not shown) to bias the substrate support 108. The formed plasma may be used to etch feature(s) in the semiconductor substrate 144 during processing and then pumped out of the process chamber 100 through the vacuum pump 134. It is to be understood that other components of the process chamber 100 have been omitted for purposes of clarity by example.

During processing, the plasma may extend not only to the semiconductor substrate 144, but also to the chamber walls. To protect the chamber walls from the plasma, the process chamber 100 can include a liner 106. The liner 106 can be removable in order to be cleaned and/or replaced.

The substrate support 108 may be biased by a DC power supply (not shown). The substrate support 108 generally includes a cathode 102, a ring assembly 104, a dielectric shield 111, and a support insulator 112. One or more of the ring assembly 104, dielectric shield 111, support insulator 112 and liner 106 may be consumed over time due to plasma exposure, and comprise a portion or all of a processing kit. The cathode 102 can be biased by a DC power source (not shown) or a radio frequency (RF) power source 126 can be optionally coupled to the cathode 102 in the substrate support 108 through a matching network 129. The cathode 102 can include an electrostatic chuck (ESC) 110 disposed thereon. The ESC 110 clamps the semiconductor substrate 144 against the cathode 102. Alternatively, a mechanical chuck (not shown) can be used to clamp the semiconductor substrate 144 against the cathode 102.

To maximize the concentration of reactive species and charged particles at the surface of the semiconductor substrate 144, RF current flow between the plasma and the cathode 102 should be concentrated in the area occupied by the semiconductor substrate 144. Thus, surfaces of the cathode 102 that are not covered by the semiconductor substrate 144 are covered by dielectric material, including the ring assembly 104 and the dielectric shield 111. The dielectric shield 111 comprises a cylinder of dielectric material that covers a side surface of the cathode 102. The ring assembly 104 rests on and overlaps a portion of the top surface of the cathode 102 that is outside of the perimeter of the semiconductor substrate 144. The support insulator 112 functions to electrical isolate the substrate support 108 from the chamber walls.

In general, the process chamber 100 includes one or more components that are exposed to plasma during processing. Each component generally includes a body having surfaces, including a first surface interfacing with another component of the process chamber 100 (“shielded surface”), and a second surface facing the processing region 114 (“a processing facing surface”). The processing facing surface is directly exposed to the environment, such as process gases and plasma, present within the processing chamber while the shielded surfaces are not directly exposed. Such components may be one or more of the ring assembly 104, the liner 106, the showerhead 123, and the like. For example, the ring assembly 104 comprises a body that has a shielded surface 105 interfacing with the substrate support 108 and a plasma facing surface 136 exposed to the processing region 114. The showerhead, 123 includes a shielded surface 121 interfacing with the lid 118 and a plasma facing surface 138 exposed to the processing region 114. The liner 106 includes a shielded surface 107 interfacing with the cylindrical side wall 128 and a plasma facing surface 140 exposed to the processing region 114.

During processing, the plasma facing surfaces 138, 136, 140 of the process chamber 100 are exposed to process gasses which erode the surfaces exposed to the plasma. The erosion of the plasma facing surfaces 138, 136, 140 create variability in the process and may be managed through preventative maintenance (PM). However, PM downtime along with the process variability on startup, add significantly to production costs for the substrates processed in the process chamber. The plasma facing surfaces 138, 136, 140 are modified with a surface profile which enlarges the surface area for the chamber component in order to extend the time between scheduled PM and reduce production costs. For example, the surface profile may be a wave-form, such as a smooth wave wave-form, a stepped wave-form, a complex wave-form, a sinusoidal wave-form or have another suitable wave-form for enlarging the surface area of the plasma facing surfaces 138, 136, 140 from a base surface. The surface profile of the plasma facing surfaces 138, 136, 140 slows the erosion of the chamber component and maintains adequate processing conditions in the processing chamber for more substrates. For example, in a semiconductor process system confirmed to etch features in dielectric materials, such as the insulating dielectric oxide of chips, consumables in the process kit include rings made of silicon, silicon dioxide or quartz, silicon carbide. If a silicon ‘insert’ ring surrounding the substrate on the electrostatic chuck (ESC) is eroded significantly, the etch rate, feature profile and CD (critical dimensions) of the chip features near the edge of the substrate would be adversely affected resulting in a dropping yield of chips per substrate. The value of each processed substrate, and the chips thereon, is many multiples times the cost of the consumable part. Thus, it is important to extend the useful life of the consumable parts. For example, each semiconductor process system may cost over $1000 per hour to operate, while it may process 5-10 substrates with potential chips worth many tens of thousands of dollars in the same hour. It is important to maximize the mean time between cleans (MTBC) and, equivalently, the mean substrates between cleans (MWBC). The shielded surfaces of the chamber components do not have a surface profile, although some component designers may include surface profiles on the shielded surfaces without determent.

As discussed above, the consumable parts of the may include one or more of the ring assembly 104, the dielectric shield 111, the support insulator 112, the liner 106 or other chamber component which is exposed to plasma during processing of the substrate. The service life of the chamber component is extended by increasing the surface area of the plasma facing surfaces 138, 136, 140 by changing the surface profile. The following discussion of the changed surface profile for the plasma facing surface will be in relation to the ring assembly 104, but it is contemplated that the surface profile may be utilized to increase the MTBC and MSBC for other consumable chamber components, such as for example, the showerhead 123, the liner 106, among others.

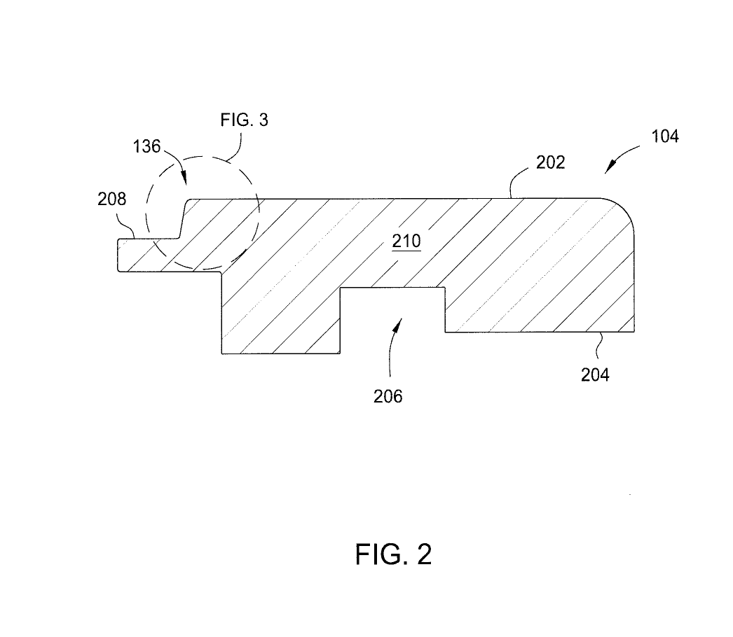

FIG. 2 is a cross-sectional side view of the ring assembly 104 according to an embodiment. The ring assembly 104 has a single-piece body 210, the body 210 having an upper surface 202 and a lower surface 204. The upper surface 202 generally defines the plasma facing surface 136 of the ring assembly 104. The lower surface 204 generally includes a seating area 208 configured to interface with the dielectric shield 111. The upper surface 202 includes a seating area 208 interfacing with the semiconductor substrate 144 during processing. In an embodiment, the seating area 208 is substantially level with the semiconductor substrate 144. Alternatively, the semiconductor substrate 144 can rest on or above at least a portion of the seating area 208.

The ring assembly 104 is formed from a dielectric material, such as silicon, silicon dioxide or quartz, silicon carbide, or the like. Alternatively, the ring assembly 104 may be formed from other materials selected in light of processing needs, for example, aluminum. In an embodiment, the ring assembly 104 can comprise a first dielectric material, and all or a portion of the upper surface 206 can be coated with a second dielectric material. For example, the ring assembly 104 can generally comprise quartz, and at least the seating area 208, and optionally the plasma facing surface 136, can be coated with silicon carbide.

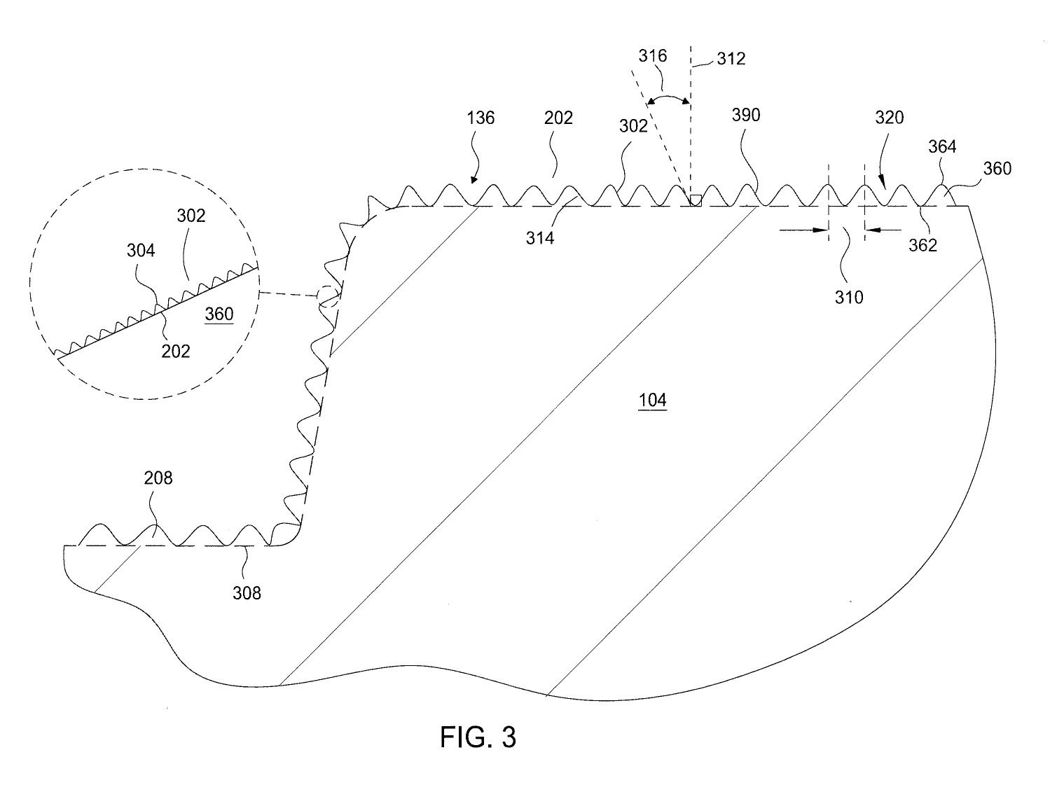

FIG. 3 is a large scale illustration for a portion of the upper surface 202 of the ring assembly 104 shown in FIG. 2 which defines the plasma facing surface 136. The plasma facing surface 136 has a base surface 308, as depicted by a dotted line, which is defines the general orientation of the plasma facing surface 136. A macro-level profile 302 is formed in the base surface 308 to create an engineered surface 390. That is, the engineered surface 390, depicted as the profile 302, is comprised of a repeatable macro-level patterned engineered surface features 360, while random micro-level patterns such as grit, bead or abrasive blasting are not. The features 360 are formed with a predetermined shape to define a determined shape of the profile 302 defined on the plasma facing surface 136. The profile 302 defined by the features 360 may have peaks 364 and valleys 362, wherein the distance between the peaks 364 and valleys 362 may define a height of the features 360. The features 360 may be separated by an interval 310. The interval 310 is also the pitch between adjacent and repeating features 360. The shape of the features 360 and distance of the interval 310 are predefined by the fabricator and/or part designer, such that there is no randomness or unpredictability associated with the shape of the features 360 and or distance of the intervals 310 which would be present in micro-level surface texturing, such as by bead or abrasive blasting. For example, there may be an identical peak 364 for each feature 360 at each increment of the interval 310 along the plasma facing surface 136 such that the features 360 defining the profile 302 for a regular (i.e., substantially identical in geometry and size) and repeating pattern.

The macro-level features 360 of the profile 302 disposed on the plasma facing surface 136 of the ring assembly 104 may be formed from the same material comprising the body 210 of the ring assembly 104. For example, the profile 302 may be formed of a dielectric material, such as quartz, silicon carbide, or the like. Alternately, the macro-level features 360 may be formed from a material covering or coating the body 210, such as yttria. The macro-level features 360 defining the profile 302 may be formed after or in conjunction with the fabrication of the ring assembly 104. For example, the profile 302 may be machined into the ring assembly 104, may be sintered with the ring assembly 104 to form a single mass, may be deposited on the ring assembly 104, may be molded and adhered to the ring assembly 104, or may be attached to the ring assembly 104, among others.

The macro-level features 360 of the profile 302 on the upper surface 202 may have a micro-level surface roughness disposed thereon. The upper surface 202, such as when it is machined or formed through other means, may have surface projections 304 on a micro-level scale defining the surface roughness of the upper surface 202 defining the profile 302. For example, the surface roughness of the profile 302 may be between 1 and 30 micro-inches. The surface roughness is comprised of random micro-level patterns formed from manufacturing processes such as grit, bead or abrasive blasting. The surface projections 304 may comprise the material of the upper surface 202 (e.g., silicon carbide). Thus, the surface projections 304 themselves may form a fractured and jagged morphology on the macro-level features 360 of the profile 302 on the upper surface 202.

The features 360 add additionally material to the surface of the ring assembly 104 and also increase the ring assembly surface area without increasing the base surface 308 of the ring assembly 104. For example, between the interval 310, a cross-section of the profile 302 shows a length larger than the base surface 308, depicted by the dotted line shown in FIG. 3. Advantageously, the surface area of the ring assembly 104 may be increase without significantly increasing material costs for the ring assembly 104.

The difference in the length of the base surface 308 and the cross-section of the profile 302 are dependent on at least the extent of the peaks 364 and valleys 362 for the profile 302 among other geometric considerations. The features 360 increase the surface area and material in the ring assembly 104. The features 360 may be sacrificially eroded to protect the ring assembly 104. That is, the features 360 are designed to erode away by the plasma and prolong, i.e., extend, the service life of the ring assembly 104 to increase the time interval between preventative maintenance as further discussed below. The modification of the profile 302 with the features 360 not only affect the surface area facing the (means of) semiconductor processing, such as process gases and plasma, but also increase useful life by an effective increase in an erosion volume for the ring assembly 104.

The sputter yield by bombardment of plasma ions versus incident angle is a nearly universal function that is maximized between 40-80 degrees to a normal of the base surface area 308 of the chamber component. Therefore, the profile 302 created on the ring assembly 104, and other consumable parts, may be arranged to maximize portions of the base surface 308 presenting an incident angle 316 of less than about 45 degrees from normal (shown by normal line 312) relative to the base surface 308. For example, the incident angle 316 of 0 (zero) degrees may be coincident with the normal line 312 while the incident angle 316 of 90 (ninety) degrees may be substantially co-planar with the base surface 308 and thus, be substantially perpendicular to the normal line 312. In one embodiment, the incident angle 316 is within about 40-80 degrees to the normal line 312. In another embodiment, the incident angle 316 may be less than about 45 degrees to the normal line 312. Thus, the profile 302 is substantially comprised of surfaces 314 angled less than about 45 degrees to the normal line 312 of the base surface 308. The plurality of profiles 302 on the ring assembly 301 provides that a majority of the surfaces 314 formed on the base surface 308 are angled at less than about 45 degrees to the normal line 312. In one embodiment, between 60 and 100 percent of the surfaces 314 308 are angled at less than about 45 degrees to the normal line 312.

In one embodiment, the ring assembly 104 includes a silicon insert ring used in chambers for etching features in silicon dioxide (SiO₂). The etch chamber uses fluorocarbon gases, like CF₄, which release F ions in the plasma state. F radicals erode the Si from the SiO₂ in the form of volatile SiF₄ which may be pumped out of the chamber without leaving residues. Silicon is often used to balance F in the chamber, since too much F can lead to loss of process selectivity between SiO2 and other layers. A natural result, however, is that F reacts with Si of the ring assembly 104, especially in the vicinity of substrate support 108 where bias RF voltage is supplied to the semiconductor substrate 144. F removes Si from the ring assembly 104 as volatile silicon-fluorine compounds. The profile 302 modifies the flat or horizontal surface of the ring assembly 104, or other silicon consumable part, with a wave-like profile. Advantageously, the profile 302 increases the surface area which provides chemical loading of the primary etchants. That is, the profile 302 slows down the vertical etch rate of the consumable part that results from the etching action. The profile 302 also increases the total volume of material that must be etched away before the consumable part reaches a minimum useful thickness and must be replaced. The profile may be designed with a maximum slope that presents angles less than 45 degrees to the normal line 312ly incident sputter ions.

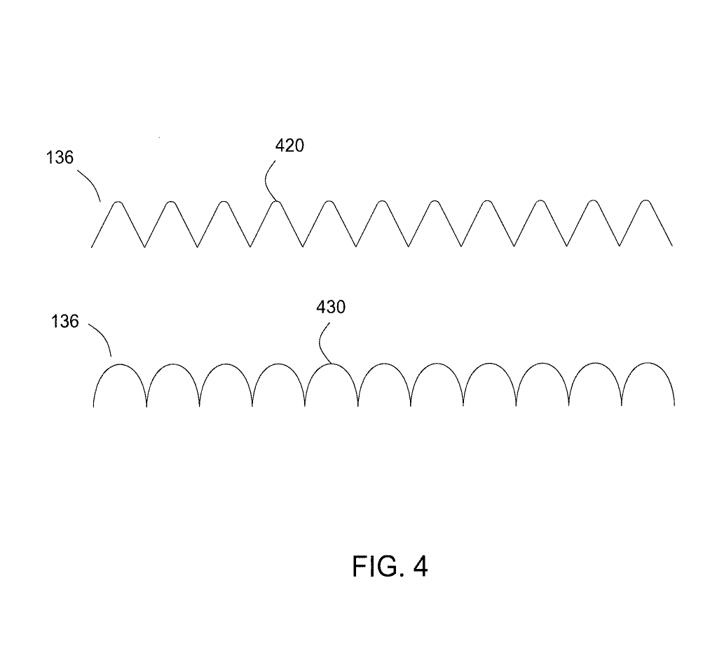

The profile 302 may be designed to minimize the physical sputtering of consumable material and faceting of sharper corners that are inevitable in parts with sharper corners. Although the sinusoidal or wave like profile is not the only possible curved profile, as shown in FIG. 3, the sinusoid profile maximizes the height of the profile for a given pitch, or pattern period. Therefore, practical representations of any multiple of one half-period of a sine wave are practical realizations for the profile 302. Turning briefly to FIG. 4. FIG. 4 illustrates a partial list of patterns suitable for use on the upper surface of the ring assembly. A semi-circular profile 430, or hemi-spherical surfaces, may also be suitable profile for a plasma facing surface. The semi-circular profile 430 has much or all of the surfaces truncated at angles below 45 degrees to normal line 312 incidence. Alternately, a trapezoidal profile 420 may be used to modify the plasma facing surface 136. As discussed above, at least the plasma facing surfaces include the profile 302, while the inclusion of profiles 302 on the shielded surfaces is optional.

The embodiments herein disclosed improvements to consumable parts for extending their useful life in etch or other semiconductor substrate processing equipment. In cases where the consumable part is worn away through action by the plasma, under the influence of bias voltage for example. Appropriate modifications are provided to form a surface profile which increases the surface area of the consumable part. The profile of the consumable part reduces the rate of erosion on the plasma facing surface exposed to processing conditions. The profile also provides for a large sacrificial volume of material that may be eroded before the part is no longer able to sustain adequate process results on the substrates. Therefore, the profile extends the service life of the consumable part and permits process equipment to run longer, reducing the time between scheduled maintenance and for the fabrication of more products, such as chips, with a lower rejection rate.

While the foregoing is directed to embodiments of the present invention, other and further embodiments of the disclosure may be devised without departing from the basic scope thereof, and the scope thereof is determined by the claims that follow.

What is claimed is:

1. A component for use in a semiconductor process chamber, comprising:
a body having an engineered surface, including:
a processing facing surface configured to face a processing region of the semiconductor process chamber; and wherein the engineered surfaces comprise:
a profile disposed on the processing facing surface comprised of a repetitive pattern of engineered macro-level features, wherein the profile is substantially comprised of surfaces angled below about 45 degrees relative to a normal of the base surface area.

2. The component of claim 1, wherein the macro-level features forming the profile further comprises:
an engineered micro-level surface features.

3. The component of claim 1, wherein the profile is a wave-form.

4. The component of claim 1, wherein the body comprises at least a portion of a ring assembly, a shield, or a chamber liner.

5. The component of claim 1, wherein the profile is machined into the body.

6. The component of claim 1, wherein the body is fabricated from silicon, silicon dioxide, quartz, silicon carbide or aluminum.

7. The component of claim 1, wherein the surface profile is formed in a coating disposed on the body.

8. The component of claim 1, wherein the processing facing surface is a plasma facing surface.

9. The component of claim 1 further comprising:
a shielded surface disposed on an opposite side of the body relative to the processing facing surface, wherein the profile is not formed on the shielded surface.

10. The component of claim 1, wherein between about 60 percent and 100 percent of the surfaces are angled below about 45 degrees to the normal of the base surface area.

11. A component for use in a semiconductor process chamber, comprising:
a body having exposed outer surfaces, the exposed outer surfaces including a shielded surface and a processing facing surface; and
a wave-form profile disposed on the processing facing surface, wherein the profile increases a surface area of the processing facing surface without increasing a base surface area.

12. The component of claim 11, wherein the wave-form profile further comprises:
an engineered micro-level surface.

13. The component of claim 12, wherein the body comprises at least a portion of a ring assembly, a shield, or a chamber liner.

14. The component of claim 12, wherein the body is fabricated from silicon, silicon dioxide, quartz, silicon carbide or aluminum.

15. The component of claim 12, wherein the wave-form profile comprises:
regularly repeating features having angles below about 45 degrees to a normal to the base surface area.

16. A method of fabricating a component for use in a semiconductor process chamber, comprising:
forming a body having exposed outer surfaces, the exposed outer surfaces including a shielded surface and a processing facing surface; and
forming a macro-level profile in the form of a wave-form on the processing facing surface.

17. The method of claim 16, wherein forming the body comprises:
sintering the body.

18. The method of claim 16, wherein between about 60 percent and 100 percent of a surface of the macro-level profile is angled below about 45 degrees to a normal of a base surface area of the processing surface.

19. The method of claim 16, wherein forming the macro-level profile further comprises:
forming a micro-level profile in the form of a wave-form on the macro-level profile.

20. The method of claim 19, wherein between about 60 percent and 100 percent of a surface of the micro-level profile is angled below about 45 degrees to a normal of a base surface area of the processing surface.
